(19) United States
(12) Patent Application Publication
(10) Pub. No.: US 2026/0196162 A1
(43) Pub. Date: Jul. 9, 2026

(54) GATE DRIVING CIRCUIT, DISPLAY PANEL AND DISPLAY APPARATUS

(71) Applicant: Tianma Advanced Display Technology Institute (Xiamen) Co., Ltd., Xiamen (CN)

(72) Inventor: Yingteng Zhai, Xiamen (CN)

(73) Assignee: Tianma Advanced Display Technology Institute (Xiamen) Co., Ltd., Xiamen (CN)

(21) Appl. No.: 19/227,411

(22) Filed: Jun. 3, 2025

(30) Foreign Application Priority Data
Jan. 7, 2025 (CN) 202510024705.5

(51) Int. Cl. G09G 3/32; G09G 3/3266; G11C 19/28

(52) U.S. Cl. CPC G09G 3/32; G09G 3/3266; G11C 19/28; G09G 2310/0267; G09G 2310/0286; G09G 2310/061; G09G 2310/08

(57) ABSTRACT

The present application discloses a gate driving circuit, a display panel, and display apparatus. The gate driving circuit includes a plurality of shift registers connected in cascade, a shift register of the shift registers including: an input module; a first control module configured to control a voltage of a third node based on the signal of the first clock terminal and a signal of the first node; a second control module configured to control a voltage of a fourth node based on the signal of the first node, a signal of the third node, a signal of a first power supply terminal, a signal of a second power supply terminal, the signal of the first clock terminal, and a signal of a second clock terminal; a third control module.

### CROSS-REFERENCE TO RELATED APPLICATION

This application claims priority to Chinese Patent Application No. 202510024705.5, filed on Jan. 7, 2025, which is hereby incorporated by reference in its entirety.

### TECHNICAL FIELD

The present application relates to the technical field of electronic products, and in particular to a gate driving circuit, a display panel, and a display apparatus.

### BACKGROUND

The gate driving circuit is one of the indispensable circuits for driving the display panel to display. The gate driving circuit generally comprises a plurality of concatenated shift registers that are electrically connected to the sub-pixels of the display panel. The signals output by the shift registers are used for controlling the states of the transistors in the sub-pixels to drive the sub-pixels to emit light.

The stability of the output signal of the shift register will affect the light-emitting effect of the sub-pixel; therefore, how to optimize the performance of the shift register is an important problem faced by those skilled in the art.

### SUMMARY

Embodiments of the present application provide a gate driving circuit, a display panel, and a display apparatus, which can improve the stability of the gate driving circuit, thereby optimizing the performance of the gate driving circuit.

In a first aspect, embodiments of the present application provide a gate driving circuit comprising: a plurality of shift registers connected in cascade, a shift register of the shift registers comprising: an input module configured to control a voltage of a first node and a voltage of a second node based on a signal of a trigger signal terminal and a signal of a first clock terminal; a first control module configured to control a voltage of a third node based on the signal of the first clock terminal and a signal of the first node; a second control module configured to control a voltage of a fourth node based on the signal of the first node, a signal of the third node, a signal of a first power supply terminal, a signal of a second power supply terminal, the signal of the first clock terminal, and a signal of a second clock terminal; a third control module configured to control the voltage of the second node based on the signal of the first node, the signal of the third node, the signal of the first power supply terminal, and the signal of the second clock terminal; and an output module configured to control a voltage of a first output terminal based on a signal of the second node, a signal of the fourth node, the signal of the first power supply terminal, and the signal of the second power supply terminal.

In a second aspect, embodiments of the present application provide a display panel including the gate driving circuit provided in embodiments in the first a second aspect. The gate driving circuit includes a plurality of shift registers connected in cascade, a shift register of the shift registers including: an input module configured to control a voltage of a first node and a voltage of a second node based on a signal of a trigger signal terminal and a signal of a first clock terminal; a first control module configured to control a voltage of a third node based on the signal of the first clock terminal and a signal of the first node; a second control module configured to control a voltage of a fourth node based on the signal of the first node, a signal of the third node, a signal of a first power supply terminal, a signal of a second power supply terminal, the signal of the first clock terminal, and a signal of a second clock terminal; a third control module configured to control the voltage of the second node based on the signal of the first node, the signal of the third node, the signal of the first power supply terminal, and the signal of the second clock terminal; and an output module configured to control a voltage of a first output terminal based on a signal of the second node, a signal of the fourth node, the signal of the first power supply terminal, and the signal of the second power supply terminal.

In a third aspect, embodiments of the present application provide a display apparatus including: a display panel provided in embodiments in the second aspect. The display panel includes a sub-pixel and a gate driving circuit which is electrically connected to the sub-pixel, where the gate driving circuit includes a plurality of shift registers connected in cascade, a shift register of the shift registers including: an input module configured to control a voltage of a first node and a voltage of a second node based on a signal of a trigger signal terminal and a signal of a first clock terminal; a first control module configured to control a voltage of a third node based on the signal of the first clock terminal and a signal of the first node; a second control module configured to control a voltage of a fourth node based on the signal of the first node, a signal of the third node, a signal of a first power supply terminal, a signal of a second power supply terminal, the signal of the first clock terminal, and a signal of a second clock terminal; a third control module configured to control the voltage of the second node based on the signal of the first node, the signal of the third node, the signal of the first power supply terminal, and the signal of the second clock terminal; and an output module configured to control a voltage of a first output terminal based on a signal of the second node, a signal of the fourth node, the signal of the first power supply terminal, and the signal of the second power supply terminal.

### BRIEF DESCRIPTION OF THE DRAWINGS

Other features, objects, and advantages of the present application will become more apparent upon reading the following detailed description of non-limiting embodiments with reference to the accompanying drawings, in which like or similar reference numerals indicate like or similar features and the accompanying drawings are not drawn to actual scale.

FIG. 1 is a schematic structural view of a display panel according to an embodiment of the present application.

FIG. 2 is a schematic structural view of a pixel driving circuit according to an embodiment of the present application.

FIG. 3 is a schematic structural view of a pixel driving circuit according to another embodiment of the present application.

FIG. 4 is a schematic structural view of a gate driving circuit according to an embodiment of the present application.

FIG. 5 is a schematic structural view of a shift register according to an embodiment of the present application.

FIG. 6 is a schematic structural view of a shift register according to a comparative example.

FIG. 7 is a schematic structural view of a shift register according to another embodiment of the present application.

FIG. 8 is a schematic structural view of a shift register according to yet another embodiment of the present application.

FIG. 9 is a schematic structural view of a shift register according to still yet another embodiment of the present application.

FIG. 10 is a schematic structural view of a shift register according to even still yet another embodiment of the present application.

FIG. 11 is a timing schematic view of a shift register according to an embodiment of the present application.

FIG. 12 is a schematic structural view of a shift register according to even still yet another embodiment of the present application.

FIG. 13 is a schematic structural view of a gate driving circuit according to another embodiment of the present application.

FIG. 14 is a schematic structural view of a shift register according to even still yet another embodiment of the present application.

FIG. 15 is a timing schematic view of a shift register according to another embodiment of the present application.

FIG. 16 is a schematic structural view of a display panel according to another embodiment of the present application.

FIG. 17 is a schematic structural view of a display apparatus according to an embodiment of the present application.

FIG. 18 is a schematic structural view of a display apparatus according to another embodiment of the present application.

### DETAILED DESCRIPTION

Reference will now be made in detail to the features and exemplary embodiments of the various aspects of the present application, and in order that the objects, aspects, and advantages of the present application will become more apparent, a more particular description of the present application will be rendered by reference to specific embodiments thereof which are illustrated in the appended drawings. It should be understood that the particular embodiments described herein are merely configured to explain the present application and are not configured to limit the present application. It will be apparent to one skilled in the art that the present application may be practiced without some of these specific details. The following description of the embodiments is merely provided to provide a better understanding of the disclosure by illustrating examples of the present application.

It is noted that relational terms such as first, second, and the like, may be used solely to distinguish one entity or action from another entity or action without necessarily requiring or implying any actual such relationship or order between such entities or actions. Moreover, the terms “comprise”, “include”, or any other variation thereof, are intended to cover a non-exclusive inclusion, such that a process, method, article, or apparatus that includes a list of elements does not include only those elements but may include other elements not expressly listed or inherent to such process, method, article, or apparatus. An element defined by “comprise . . . ” does not, without more constraints, preclude the existence of additional identical elements in the process, method, article, or apparatus that comprises the element.

It will be understood that when a layer, or region, is referred to as being “on” or “over” another layer, or region, in describing the structure of a component, it can be directly on the other layer, or region, or it can include other layers or regions between it and the other layer, or region. Also, if the part is turned over, the one layer, one region, will be positioned “under” or “under” the other layer, or the other region.

It is to be understood that the term “and/or” as used herein is merely an association that describes an associated object and that there may be three relationships, e.g. A and/or B, which may represent: there are three cases of A alone, A and B together, and B alone. In addition, the character “/”, as used herein, generally indicates that the context object is an “or” relationship.

In embodiments of the present application, the term “electrically connected” may refer to a direct electrical connection between two components, or may refer to an electrical connection between two components via one or more other components. The term “drive” may refer to either “control” or “operation”. The display panel may be a display apparatus or a module/portion of a display apparatus.

In the embodiments of the present application, a transistor means an element including at least three terminals of a gate electrode, a source electrode, and a drain electrode. A transistor has a channel region between a drain (drain terminal, drain region, or drain electrode) and a source (source electrode terminal, source region, or source electrode), and current can flow through the source, channel region, and drain. The channel region refers to a region through which a current mainly flows. In the embodiments of the present application, the functions of the “source” and “drain” are sometimes interchanged with each other, i.e. the “source” and “drain” can be interchanged with each other, in the case where transistors of opposite polarities are used, or in the case of a change in the direction of current flow in the operation of the circuit, etc. In the embodiments of the present application, for any one transistor, one of the “source” and “drain” is referred to as the first electrode of the transistor, and the other is referred to as the second electrode of the transistor, with the gate being the control terminal of the transistor. In embodiments of the present application, at least a portion of the signal has a high voltage and a low voltage; one of a high voltage and a low voltage may serve as a gate voltage of the signal, and the gate voltage of the signal may cause the controlled transistor to conduct; the other of the high voltage and the low voltage may act as a cut-off voltage for the signal, which may turn off the controlled transistor. For example, for a signal that is configured to control a P-type transistor (the signal can be applied to the gate of the P-type transistor), the turn-on voltage is low and the turn-off voltage is high. By way of further example, for a signal that is configured to control an N-type transistor (which can be applied to the gate of the N-type transistor), the turn-on voltage is high and the turn-off voltage is low. Herein, “voltage” may also be referred to as “level”, “potential”. “cut-off” may also be referred to as “turn-off”, or “off”.

It will be apparent to those skilled in the art that various modifications and variations can be made in the present application without departing from the spirit or scope of the application. Thus, it is intended that the present application covers the modifications and variations of the present application that come within the scope of the appended claims and their equivalents. It is to be noted that the embodiments provided by embodiments of the present application can be combined with each other without being contradictory.

Embodiments of the present application provide a gate driving circuit, a display panel, and a display apparatus, and various embodiments of the present application will be described below with reference to the drawings.

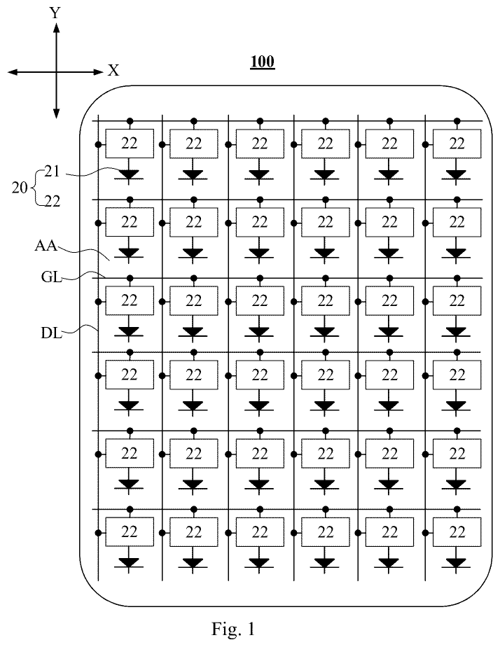

Embodiments of the present application provide a display panel. As shown in FIG. 1, the display panel 100 is provided with sub-pixels 20 distributed in an array. The sub-pixel 20 includes a light-emitting element 21 and a pixel driving circuit 22 driving the light-emitting device.

Referring to FIG. 1, a display panel 100 is provided with a plurality of scanning lines GL extending in a first direction X in a display area AA. Taking the first direction X as an example, each scanning line GL and each sub-pixel row are arranged in a one-to-one correspondence. The pixel driving circuit 22 in each sub-pixel of the sub-pixel row is electrically connected to the corresponding scanning line GL. The display panel 100 is further provided with a plurality of data lines DL extending in a second direction Y in the display area AA, the second direction Y intersecting the first direction X. Taking the second direction Y as an example, each data line DL and each sub-pixel column are arranged in a one-to-one correspondence. The pixel driving circuit 22 in each sub-pixel of the sub-pixel column is electrically connected to the corresponding data line DL. In this manner, the pixel driving circuit 22 in each sub-pixel is connected to the scanning line GL and the data line DL. The scanning line GL is loaded with a scanning signal to control the state of the pixel driving circuit 22.

It can be understood that, in the example of FIG. 1, only one scan line GL corresponding to the sub-pixel row is illustrated. If necessary, the display panel 100 may be provided with a plurality of different scanning lines GL corresponding to the sub-pixel rows. A data voltage Vdata for driving the pixel driving circuit 22 can be loaded on the data line DL, and the pixel driving circuit 22 can drive the light-emitting element 21 according to the written data voltage Vdata, thereby controlling the brightness of the light-emitting element 21. It can be understood that the pixel driving circuit 22 may also control the brightness of the light-emitting element 21 according to other signals.

Illustratively, the pixel driving circuit 22 at least includes a data write transistor, a drive transistor, and a storage capacitor. The gate of the drive transistor may be electrically connected to one of the electrode plates of the storage capacitor. A source of the data write transistor may be electrically connected to the data line DL, and a gate of the data write transistor may be electrically connected to a write control wiring for loading a data write signal (i.e. a kind of scan signal). The pixel driving circuit 22 is configured such that the data write transistor is turned on when a selective voltage of the data write signal is loaded on the write control wiring, which in turn causes the driving voltage on the data line DL to be written to the gate of the driving transistor and the storage capacitor. When the data write transistor is turned off, the drive voltage can be held by the storage capacitor. The drive transistor can output a drive current to drive the light-emitting element 21 to emit light under the control of the voltage on the gate thereof. It can be understood that the pixel driving circuit 22 of embodiments of the present application may further include other transistors or capacitors, so that the pixel driving circuit 22 has better drive performance. For example, the pixel driving circuit 22 may be a 7TIC (i.e. 7 transistors and one capacitor), an 8TIC (i.e. 8 transistors and one capacitor), or other architecture pixel driving circuits.

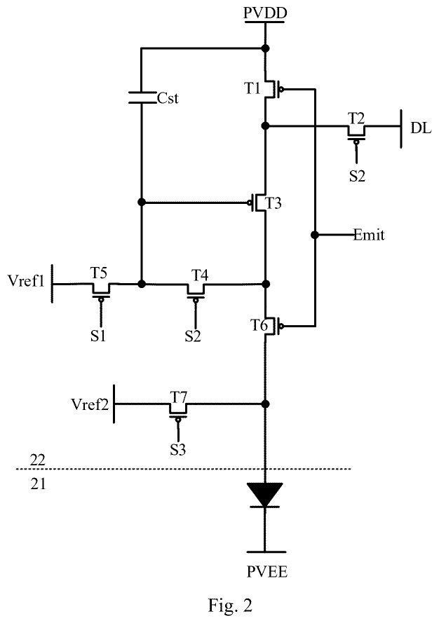

As an example, the pixel driving circuit 22 is a 7TIC architecture, as shown in FIG. 2. A transistor T2 is configured to write a data signal on a data line DL into a driving transistor T3 which is configured to generate a driving current; a transistor T4 is configured to compensate a threshold voltage of the driving transistor T3; a transistor T5 is configured to transmit a reset signal on a first reset signal line Vref1 to a gate of the driving transistor T3; a transistor T7 is configured to transmit a reset signal on a second reset signal line Vref2 to a first electrode of the light-emitting element 21; the transistor T1 and a transistor T6 are configured to control whether the light-emitting element 21 emits light or not. In addition, each of S1-S3 and Emit is a scanning signal, and Emit can also be referred to as a light-emitting control signal.

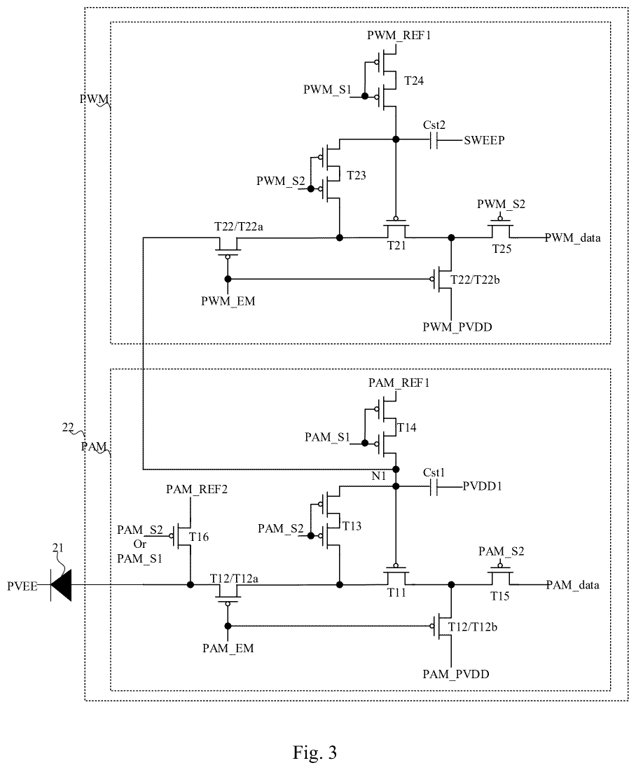

As another example, the pixel driving circuit 22 is a 13T2C architecture, as shown in FIG. 3, which comprises a PAM module and a PWM module, the PWM module being electrically connected to the PAM module, and the PAM module being electrically connected to the first electrode of the light-emitting element 21. In addition, PAM_S1, PAM_S2, PAM EM, PWM_S1, PWM_S2, and PWM_EM are scanning signals, and PAM EM and PWM EM may also be referred to as light emission control signals.

Illustratively, the light-emitting element 21 may be a current-driven self-light-emitting element such as any one of an organic light-emitting diode (OLED), a polymer light-emitting diode (PLED), a quantum dot light-emitting diode (QLED), a micro light-emitting diode (micro LED), a mini light-emitting diode (MiNi LED), and the like.

In this embodiment, the light-emitting element 21 may include light-emitting elements 21 of a plurality of different colors, including, for example, a red sub-pixel for emitting red light, a blue sub-pixel for emitting blue light, and a green sub-pixel for emitting green light.

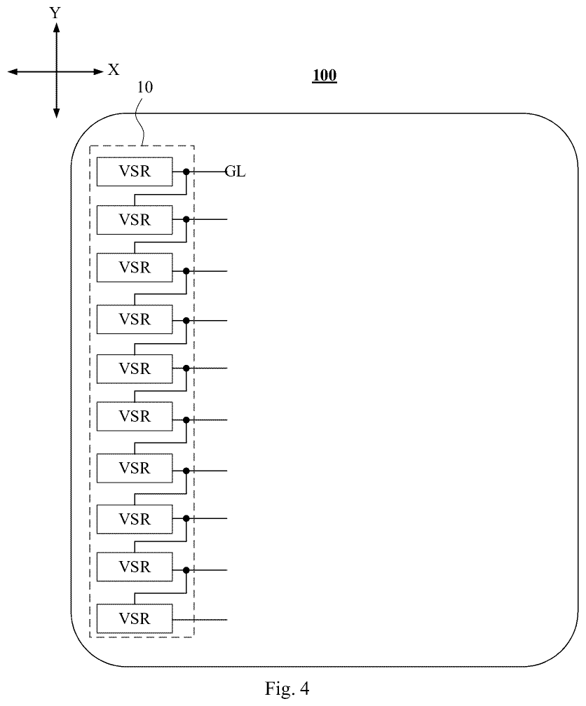

Referring to FIG. 4, in the display panel 100, a gate driving circuit 10 is further provided, which is electrically connected to a sub-pixel 20 and provides a scanning signal to the pixel driving circuit 22. Illustratively, a plurality of gate driving circuits may be provided to provide different scanning signals respectively according to the requirements of the pixel driving circuit 22. It is also possible to enable some of the scanning signals to share one gate driving circuit.

For example, the gate driver circuit 10 may supply the signal Emit to the pixel driver circuit shown in FIG. 2. As another example, the gate driver circuit 10 may provide the signal PWM_EM to the pixel driver circuit shown in FIG. 3, or the gate driver circuit 10 may provide the signal PAM_EM to the pixel driver circuit shown in FIG. 3, or the gate driver circuit 10 may provide the signal PWM_EM and the signal PAM_EM to the pixel driver circuit shown in FIG. 3.

As an example, the gate driving circuit 10 is located at a border region 220 of the display panel which is a non-display area.

As another example, the gate driving circuit 10 is located at the display area of the display panel to realize a narrow border or even no border.

Illustratively, the scan signal may include, but is not limited to, one or more of the following signals, depending on the requirements of the pixel driving circuit: a light emission control signal for controlling the pixel driving circuit to output a drive current, a write control signal for controlling a data voltage to be written into the pixel driving circuit, and a reset control signal for controlling the resetting of the pixel driving circuit, etc. For example, the scanning signal includes the signal Emit shown in FIG. 2. As another example, the scan signal includes the signal PWM_EM shown in FIG. 3, the scan signal includes the signal PAM_EM shown in FIG. 3, or the scan signal includes the signal PWM_EM and the signal PAM_EM shown in FIG. 3.

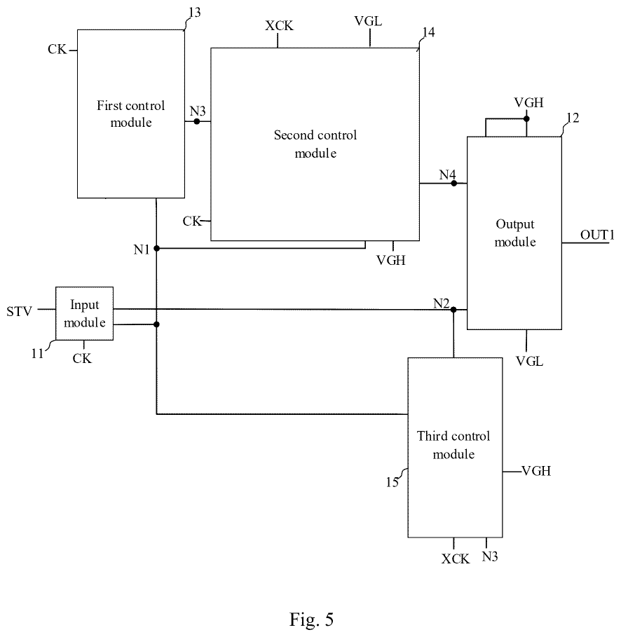

Referring to FIG. 5, a gate driving circuit 10 provided by an embodiment of the present application includes a plurality of shift registers VSR connected in cascade, and each of the shift registers VSR includes an input module 11, an output module 12, a first control module 13, a second control module 14, and a third control module 15.

The input module 11 is configured to control the voltage of the first node N1 and the voltage of the second node N2 based on the signals of the trigger signal terminal STV and the first clock terminal CK; the first control module 13 is configured to control the voltage of the third node N3 based on the signals of the first clock terminal CK and the first node N1; the second control module 14 is configured to control the voltage of the fourth node N4 based on the signals of the first node N1, the third node N3, the first power supply terminal VGH, the second power supply terminal VGL, the first clock terminal CK, and the second clock terminal XCK; the third control module 15 is configured to control the voltage of the second node N2 based on the signals of the first node N1, the third node N3, the first power supply terminal VGH, and the second clock terminal XCK; the output module 12 is configured to control the voltage of the first output terminal OUT1 based on the signals of the second node N2, the fourth node N4, the first power supply terminal VGH, and the second power supply terminal VGL.

It can be understood that the input module 11 is electrically connected to the trigger signal terminal STV, the first clock terminal CK, the first node N1 and the second node N2; the first control module 13 is electrically connected to the first clock terminal CK, the first node N1, and the third node N3; the second control module 14 is electrically connected to the first node N1, the third node N3, the first power supply terminal VGH, the second power supply terminal VGL, the first clock terminal CK, the second clock terminal XCK, and the fourth node N4; the third control module 15 is electrically connected to the first node N1, the third node N3, the first power supply terminal VGH, the second clock terminal XCK, and the second node N2; the output module 12 is electrically connected to the second node N2, the fourth node N4, the first power supply terminal VGH, the second power supply terminal VGL, and the first output terminal OUT1.

The trigger signal terminal STV is configured to provide a trigger signal, and when the trigger signal is a gate voltage, the shift register is triggered to operate. In the plurality of shift registers connected in cascade, a trigger signal terminal STV of a first stage shift register is electrically connected to a driving chip, and a trigger signal terminal STV of an (i+1)^{th} stage shift register is electrically connected to a first output terminal OUT1 of the ith stage shift register, i being an integer greater than 0. In other words, the signal output from the first output terminal OUT1 of the ith stage shift register serves as a trigger signal for the (i+1)^{th} stage shift register.

The first clock terminal CK and the second clock terminal XCK are used for providing a clock signal which comprises a signal with alternating high and low voltages. The first clock signal at the first clock terminal CK and the second clock signal at the second clock terminal XCK are phase-inverted.

The first power supply terminal VGH is used to provide a high voltage signal, and the second power supply terminal VGL is used to provide a low voltage signal.

The input module 11, the output module 12, the first control module 13, the second control module 14, and the third control module 15 cooperate with each other to enable the first output terminal OU1 to output a scanning signal which is used for driving a pixel driving circuit to control the light-emitting effect of a sub-pixel. The output module 12 is controlled by the second node N2, and the stability of the voltage of the second node N2 will affect the stability of the signal output by the first output terminal OU1. That is, the voltage stability of the second node N2 affects the light-emitting effect of the sub-pixel.

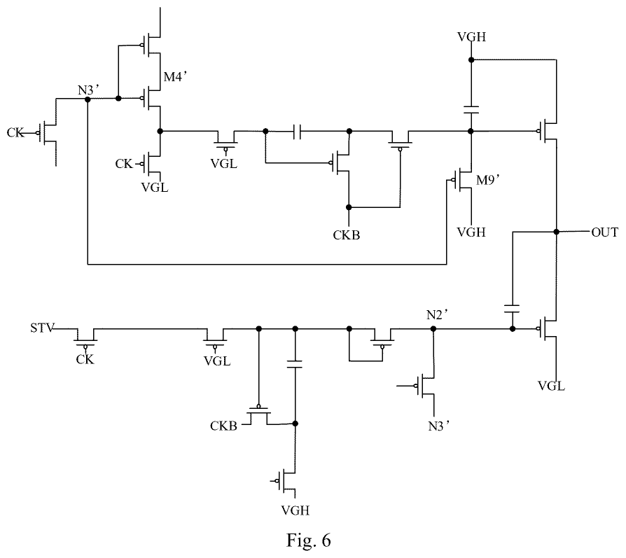

In order to better illustrate the advantages of the embodiments of the present application, referring to FIG. 5 and FIG. 6 for comparison, in which the node N2′ in FIG. 6 is equivalent to the second node N2 in FIG. 3, the node N3′ in FIG. 6 is equivalent to the third node N3 in FIG. 5, the node N4′ in FIG. 6 is equivalent to the fourth node N4 in FIG. 5, the gate of the transistor M11′ in FIG. 6 is connected to the node N2′, which is controlled by the node N3′. The node N3′ also needs to control a transistor M4′, and a transistor M9′. Therefore, it is easily disturbed by the transistor M4′ and the transistor M9′ to disturb the potential of the node N2′, resulting in a decrease in the circuit stability.

However, according to the embodiments of the present application, the third node is configured to control the second control circuit and the third control circuit, simplifying the connection relationship of the third node; the third node no longer directly is configured to control the second node and does not directly interfere with the potential of the second node, thereby reducing the signal interference of the second node and improving circuit stability, thereby optimizing the performance of the gate driving circuit.

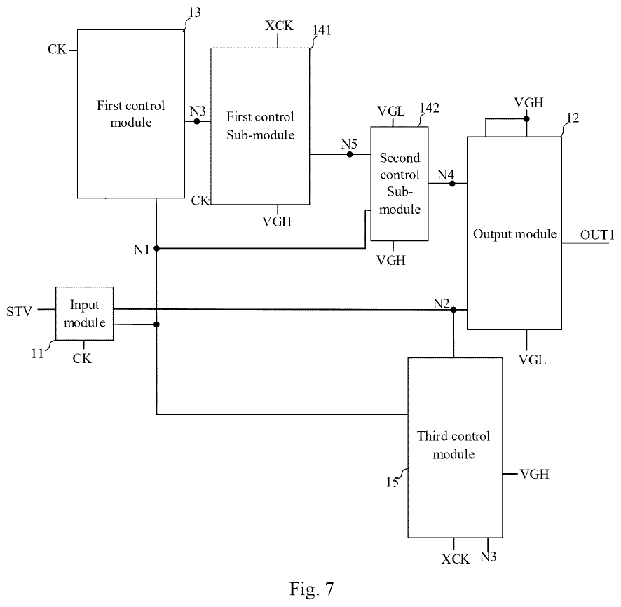

In some embodiments, as shown in FIG. 7, the second control module includes a first control sub-module 141 and a second control sub-module 142. The first control sub-module 141 is configured to control the voltage of the fifth node N5 based on the signals of the third node N3, the first power supply terminal VGH, the first clock terminal CK, and the second clock terminal XCK; the second control sub-module 142 is configured to control the voltage of the fourth node N4 based on the signals of the first node N1, the fifth node N5, the first power supply terminal VGH, and the second power supply terminal VGL.

It can be understood that the first control sub-module 141 is electrically connected to the third node N3, the first power supply terminal VGH, the first clock terminal CK, the second clock terminal XCK, and the fifth node N5. The second control sub-module 142 is electrically connected to the first node N1, the fifth node N5, the first power supply terminal VGH, the second power supply terminal VGL, and the fourth node N4.

In this embodiment, the second control module is divided into the first control sub-module 141 and the second control sub-module 142. The signal of the third node N3 affects the voltage of the fifth node N5, and the signal of the fifth node N5 and a signal of the first node N1 affect the voltage of the fourth node N4, thereby enhancing the control accuracy.

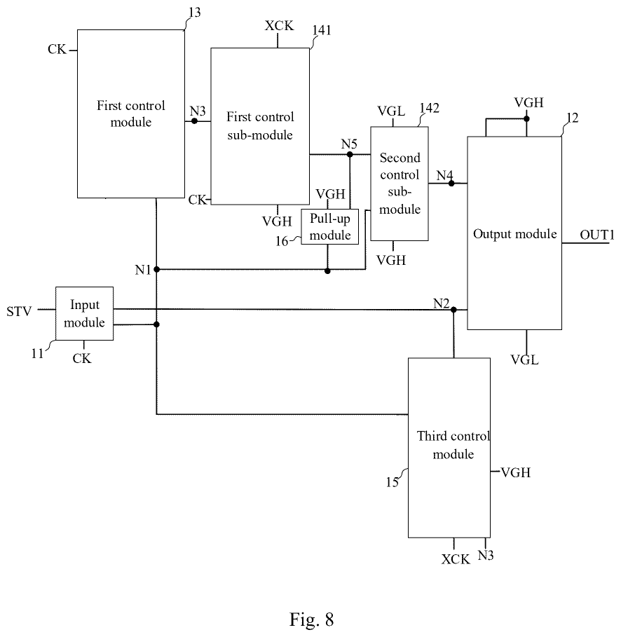

In some embodiments, as shown in FIG. 8, the shift register further includes a pull-up module 16 controlling the voltage of the first node N1 based on the signals of the fifth node N5 and the first power supply terminal VGH.

Illustratively, when the fifth node N5 is at a low voltage, the pull-up module 16 is turned on, and the high voltage of the first power supply terminal VGH is transmitted to the first node N1. Therefore, when the fifth node N5 is at a low voltage, the pull-up module 16 is configured to lock the potential of the first node N1, thereby increasing the potential stability of the first node N1.

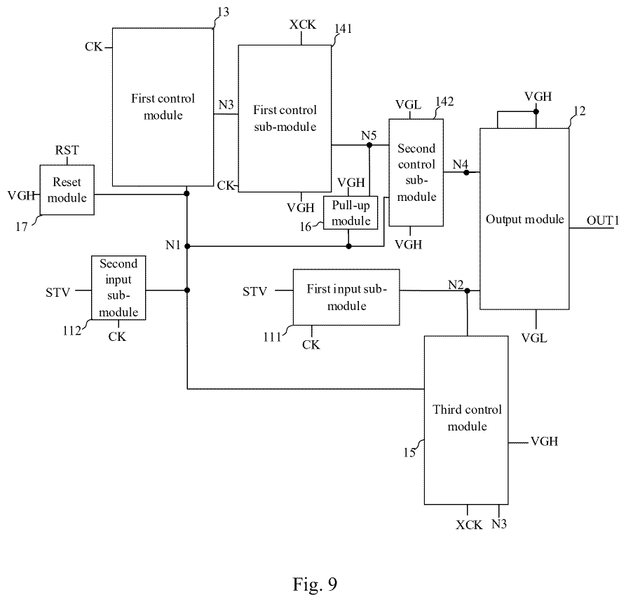

In some embodiments, as shown in FIG. 9, the shift register further includes a reset module 17 which is configured to control the voltage of the first node N1 based on the signals of the first power supply terminal VGH and the reset signal terminal RST.

Illustratively, when the signal of the reset signal terminal RST is a low voltage, the reset module 17 is turned on, and the high voltage of the first power supply terminal VGH is transmitted to the first node N1.

It can be ensured that the circuit can be restored to a known determined state in an initial state or in an error state, thereby increasing the reliability of the circuit by providing a reset module.

In some embodiments, as shown in FIG. 9, the input module 11 includes a first input sub-module 111 and a second input sub-module 112. The first input sub-module 111 is configured to control the voltage of the second node N2 based on the signals of the trigger signal terminal STV and the first clock terminal CK; the second input sub-module 112 is configured to control the voltage of the first node N1 based on the signals of the trigger signal terminal STV and the first clock terminal CK.

For example, when the signal of the first clock terminal CK is a low voltage, the first input sub-module 111 and the second input sub-module 112 are turned on, the signal of the trigger signal terminal STV is transmitted to the second node N2 via the first input sub-module 111, and the signal of the trigger signal terminal STV is transmitted to the first node N1 via the second input sub-module 112.

In this embodiment, different input sub-modules are used to respectively transmit the signal of the trigger signal terminal STV to the first node N1 and the second node N2 to realize the input control to the first node N1 and the second node N2, thereby avoiding the voltage of the first node N1 interfering with the voltage of the second node N2, and further improving the potential stability of the second node N2.

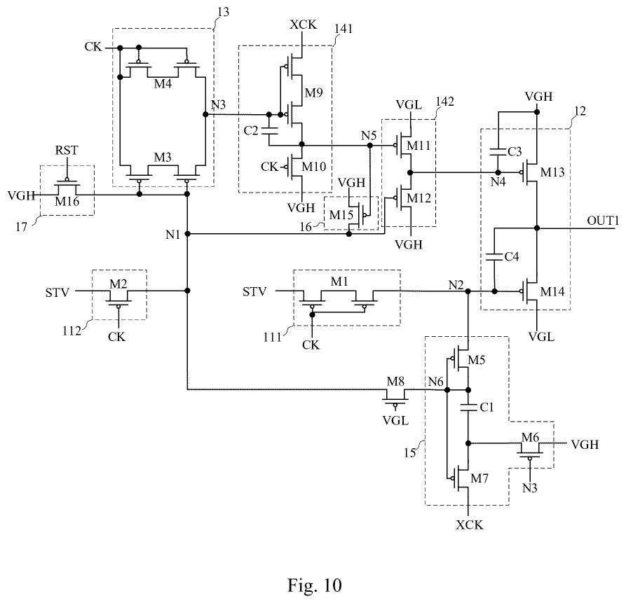

In some embodiments, as shown in FIG. 10, the first input sub-module 111 includes a first transistor M1; a first electrode of the first input sub-module 111 is electrically connected to the trigger signal terminal STV, a second electrode of the first input sub-module 111 is electrically connected to the second node N2, and a gate of the first input sub-module 111 is electrically connected to the first clock terminal CK. The second input sub-module 112 includes a second transistor M2; a first electrode of the second transistor M2 is electrically connected to the trigger signal terminal STV, a second electrode of the second transistor M2 is electrically connected to the first node N1, and a gate of the second transistor M2 is electrically connected to the first clock terminal CK.

Illustratively, when the first clock signal of the first clock terminal CK is a low voltage, the first transistor M1 and the second transistor M2 are turned on, the trigger signal on the trigger signal terminal STV is transmitted to the second node N2 via the first transistor M1, and the trigger signal on the trigger signal terminal STV is transmitted to the first node N1 via the second transistor M2.

Illustratively, as shown in FIG. 10, the first transistor M1 is a double-gate transistor, or, the channel length of the first transistor M1 is greater than that of the second transistor M2. The first transistor employs a double-gate transistor or a transistor having a long channel length, which can reduce the leakage current, thereby further ensuring the potential stability of the second node. Herein, a transistor is a double-gate transistor and includes two sub-transistors connected in series, the gates of the two sub-transistors being electrically connected. For example, taking the example where the first transistor M1 includes two sub-transistors, a first electrode of the first sub-transistor is electrically connected to the trigger signal terminal STV, a second electrode of the first sub-transistor is electrically connected to a first electrode of the second sub-transistor, a second electrode of the second sub-transistor is electrically connected to the second node N2, and a gate of the first sub-transistor and a gate electrode of the second sub-transistor are electrically connected to the first clock terminal.

In some embodiments, as shown in FIG. 10, the first control module 13 includes a third transistor M3 and a fourth transistor M4; a first electrode of the third transistor M3 is electrically connected to the first clock terminal CK, a second electrode of the third transistor M3 is electrically connected to the third node N3, and a gate of the third transistor M3 is electrically connected to the first node N1; a first electrode and a gate of the fourth transistor M4 are electrically connected to the first clock terminal CK, and a second electrode of the fourth transistor M4 is electrically connected to the third node N3.

Illustratively, when the first node N1 is at a low voltage, the third transistor M3 is turned on, and the first clock signal on the first clock terminal CK is transmitted to the third node N3 through the third transistor M3. When the first clock signal on the first clock terminal CK is at a low voltage, the fourth transistor M4 is turned on, and the first clock signal on the first clock terminal CK is transmitted to the third node N3 via the fourth transistor M4.

Illustratively, as shown in FIG. 10, at least one of the third transistor M3 and the fourth transistor M4 is a double-gate transistor, or the channel length of at least one of the third transistor M3 and the fourth transistor M4 is greater than the channel length of the second transistor M2. Illustratively, the third transistor M3 and the fourth transistor M4 are illustrated in FIG. 8 as double-gate transistors.

The third transistor M3 and/or the fourth transistor M4 adopt a double-gate transistor or a transistor having a long channel length, which can reduce the leakage current, thereby ensuring the potential stability of the third node.

In some embodiments, as shown in FIG. 10, the third control module 15 includes a fifth transistor M5, a sixth transistor M6, a seventh transistor M7, and a first capacitor C1. A first electrode and a gate of the fifth transistor M5 are electrically connected to the sixth node N6, and a second electrode of the fifth transistor M5 is electrically connected to the second node N2; a first electrode of the sixth transistor M6 is electrically connected to the first power supply terminal VGH, a second electrode of the sixth transistor M6 is electrically connected to a first electrode of the first capacitor C1, and a gate of the sixth transistor M6 is electrically connected to the third node N3; a first electrode of the seventh transistor M7 is electrically connected to the second clock terminal XCK, a second electrode of the seventh transistor M7 is electrically connected to a first electrode of the first capacitor C1, and a gate of the seventh transistor M7 is electrically connected to the sixth node N6; a second electrode of the first capacitor C1 is electrically connected to a sixth node N6 which is electrically connected to the first node N1.

Illustratively, when the sixth node N6 is at a low voltage, the fifth transistor M5 and the seventh transistor M7 are turned on. When the third node N3 is low, the sixth transistor M6 is turned on.

When the first electrode of the first capacitor C1 changes from a high voltage to a low voltage, the potential of the sixth node N6 becomes lower due to the coupling effect of the first capacitor C1, so that the fifth transistor M5 is turned on more sufficiently, and the potential of the second node N2 is maintained at a low potential.

In some embodiments, as shown in FIG. 10, the sixth node N6 is electrically connected to the first node N1 via an eighth transistor M8, and a gate of the eighth transistor M8 is electrically connected to the second power supply terminal VGL. The eighth transistor M8 can be maintained in a conductive state via the second power supply terminal VGL.

In this embodiment, the eighth transistor M8 can isolate the first node N1 from the sixth node N6, so that the voltage of the first node N1 can be relatively stably maintained. For example, the voltage of the first node N1 does not decrease to be lower than the voltage of the second power supply terminal VGL, so that the bias stress applied to the transistor to which the first node N1 is connected can be alleviated.

Illustratively, the channel length of the eighth transistor may be greater than that of the transistors in the output module. In this way, the leakage current of the eighth transistor can be reduced, so that the first node N1 and the sixth node N6 are better isolated.

In some embodiments, as shown in FIG. 10, the first control sub-module 141 includes a ninth transistor M9, a tenth transistor M10, and a second capacitor C2; a first electrode of the ninth transistor M9 is electrically connected to the second clock terminal XCK, a second electrode of the ninth transistor M9 is electrically connected to the fifth node N5, and a gate of the ninth transistor M9 is electrically connected to the third node N3; a first electrode of the tenth transistor M10 is electrically connected to the first power supply terminal VGH, a second electrode of the tenth transistor M10 is electrically connected to the fifth node N5, and a gate of the tenth transistor M10 is electrically connected to the first clock terminal CK; a first electrode of the second capacitor C2 is electrically connected to the third node N3, and a second electrode of the second capacitor C2 is electrically connected to the fifth node N5.

Illustratively, when the third node N3 is at a low voltage, the ninth transistor M9 is turned on, and the second clock signal of the second clock terminal XCK is transmitted to the fifth node N5. When the first clock signal of the first clock terminal CK is at a low voltage, the tenth transistor M10 is turned on, and the high voltage of the first power supply terminal VGH is transmitted to the fifth node N5. The two electrodes of the second capacitor C2 are connected to the third node N3 and the fifth node N5 respectively, and the voltage of any one of the third node N3 and the fifth node N5 jumps, and under the coupling effect of the second capacitor C2, the voltage of the other of the third node N3 and the fifth node N5 also jumps.

Illustratively, the ninth transistor M9 is a double-gate transistor, or the channel length of the ninth transistor M9 is greater than that of the transistors in the output module, to reduce the possibility of leakage current in the ninth transistor M9, thereby improving the potential stability of the fifth node N5.

In some embodiments, as shown in FIG. 10, the second control sub-module 142 includes an eleventh transistor M11 and a twelfth transistor M12; a first electrode of the eleventh transistor M11 is electrically connected to the second power supply terminal VGL, a second electrode of the eleventh transistor M11 is electrically connected to the fourth node N4, and a gate of the eleventh transistor M11 is electrically connected to the fifth node N5; a first electrode of the twelfth transistor M12 is electrically connected to the first power supply terminal VGH, a second electrode of the twelfth transistor M12 is electrically connected to the fourth node N4, and a gate of the twelfth transistor M12 is electrically connected to the first node N1.

Illustratively, when the fifth node N5 is at a low voltage, the eleventh transistor M11 is turned on, and the low voltage of the second power supply terminal VGL is transmitted to the fourth node N4. When the first node N1 is at a low voltage, the twelfth transistor M12 is turned on, and the high voltage of the first power supply terminal VGH is transmitted to the fourth node N4, thereby locking the potential of the fourth node N4.

In some embodiments, as shown in FIG. 10, the output module 12 includes a thirteenth transistor M13, a fourteenth transistor M14, a third capacitor C3, and a fourth capacitor C4; a first electrode of the thirteenth transistor M13 is electrically connected to the first power supply terminal VGH, a second electrode of the thirteenth transistor M13 is electrically connected to the first output terminal OUT1, and a gate of the thirteenth transistor M13 is electrically connected to the fourth node N4; a first electrode of the fourteenth transistor M14 is electrically connected to the second power supply terminal VGL, a second electrode of the fourteenth transistor M14 is electrically connected to the first output terminal OUT1, and a gate of the fourteenth transistor M14 is electrically connected to the second node N2; the third capacitor C3 is electrically connected between the first power supply terminal VGH and the fourth node N4; a fourth capacitor C4 is electrically connected between the second node N2 and the first output terminal OUT1.

Illustratively, when the fourth node N4 is at a low voltage, the thirteenth transistor M13 is turned on, the high voltage of the first power supply terminal VGH is transmitted to the first output terminal OU1, and the first output terminal OU1 outputs the high voltage. When the second node N2 is at a low voltage, the fourteenth transistor M14 is turned on, and the voltage of the second power supply terminal VGL is transmitted to the first output terminal OU1, and the first output terminal OU1 outputs the voltage of the second power supply terminal VGL.

Illustratively, the channel width-to-length ratios of the thirteenth transistor M13 and the fourteenth transistor M14 are the same, and the channel width-to-length ratio of the thirteenth transistor M13 is greater than that of the transistors of any one of the input module 11, the first control module 13, the second control module 14, the third control module 15, the pull-up module 16, and the reset module 17, so that the driving capability of the signal output from the first output terminal OU1 can be ensured.

In some embodiments, as shown in FIG. 10, the pull-up module 16 includes a fifteenth transistor M15; a first electrode of the fifteenth transistor M15 is electrically connected to the first power supply terminal VGH, a second electrode of the fifteenth transistor M15 is electrically connected to the first node N1, and a gate of the fifteenth transistor M15 is electrically connected to the fifth node N5.

Illustratively, when the fifth node N5 is at a low voltage, the fifteenth transistor M15 is turned on, and the high voltage of the first power supply terminal VGH is transmitted to the first node N1, thereby locking the potential of the first node N1 and improving the potential stability of the first node N1.

In some embodiments, as shown in FIG. 10, the reset module 17 includes a sixteenth transistor M16; a first electrode of the sixteenth transistor M16 is electrically connected to the first power supply terminal VGH, a second electrode of the sixteenth transistor M16 is electrically connected to the first node N1, and a gate of the sixteenth transistor M16 is electrically connected to the reset signal terminal RST.

Illustratively, when the reset signal of the reset signal terminal RST is at a low voltage, the sixteenth transistor M16 is turned on, and the high voltage of the first power supply terminal VGH is transmitted to the first node N1, and the potential of the first node N1 is reset.

It should be noted that, in the above examples, each transistor is a P-type transistor, and in other examples, each transistor in the shift register may be an N-type transistor; alternatively, part of the transistors in the shift register are P-type transistors and the other part of the transistors are N-type transistors.

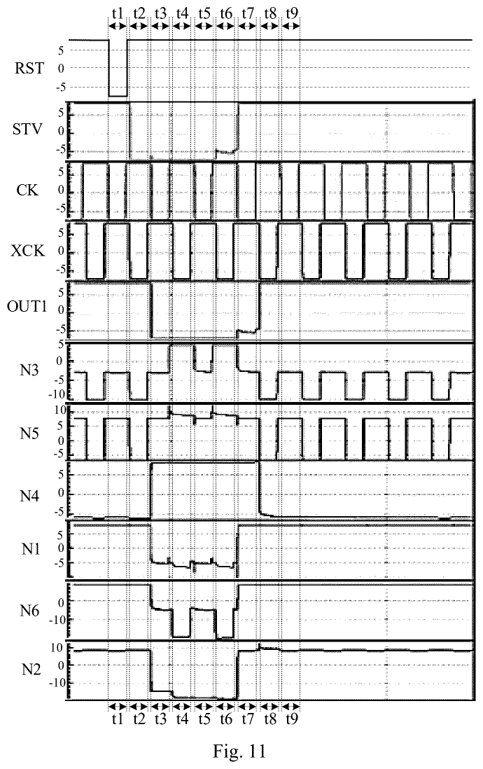

The operation of the shift register will be described with reference to FIGS. 10 and 11 by taking the example where each transistor is a P-type transistor.

The working process of the shift register includes a first stage t1 to a ninth stage t9, where “0” in table 1 indicates that the gate of the transistor is connected to a low voltage, and the transistor is turned on, “1” indicates that a high voltage is applied to the gate of the transistor and the transistor is switched off. Here, “low voltage” and “high voltage” are relative terms, and “low voltage” refers to a voltage at which the control transistor is turned on, and “high voltage” refers to a voltage at which the control transistor is turned off. The specific value of the “low voltage” to which different transistors are applied may be different, and the specific value of the “high voltage” to which different transistors are applied may be different.

TABLE 1

| | t1 | t2 | t3 | t4 | t5 | t6 | t7 | t8 | t9 |
|---|---|---|---|---|---|---|---|---|---|
| M1 | 0 | 1 | 0 | 1 | 0 | 1 | 0 | 1 | 0 |
| M2 | 0 | 1 | 0 | 1 | 0 | 1 | 0 | 1 | 0 |
| M3 | 1 | 1 | 0 | 0 | 0 | 0 | 1 | 1 | 1 |
| M4 | 0 | 1 | 0 | 1 | 0 | 1 | 0 | 1 | 0 |
| M5 | 1 | 1 | 0 | 0 | 0 | 0 | 1 | 1 | 1 |
| M6 | 0 | 0 | 0 | 1 | 0 | 1 | 0 | 0 | 0 |
| M7 | 1 | 1 | 0 | 0 | 0 | 0 | 1 | 1 | 1 |
| M8 | 0 | 0 | 0 | 0 | 0 | 0 | 0 | 0 | 0 |
| M9 | 0 | 0 | 0 | 1 | 0 | 1 | 0 | 0 | 0 |
| M10 | 0 | 1 | 0 | 1 | 0 | 1 | 0 | 1 | 0 |
| M11 | 1 | 0 | 1 | 1 | 1 | 1 | 1 | 0 | 1 |
| M12 | 1 | 1 | 0 | 0 | 0 | 0 | 1 | 1 | 1 |
| M13 | 0 | 0 | 1 | 1 | 1 | 1 | 1 | 0 | 0 |
| M14 | 1 | 1 | 0 | 0 | 0 | 0 | 1 | 1 | 1 |
| M15 | 1 | 0 | 1 | 1 | 1 | 1 | 1 | 0 | 1 |
| M16 | 0 | 1 | 1 | 1 | 1 | 1 | 1 | 1 | 1 |

In each stage, the first power supply terminal VGH maintains a high voltage, and the second power supply terminal VGL maintains a low voltage.

In the first stage t1, the reset signal terminal RST is at a low voltage, the trigger signal terminal STV is at a high voltage, the first clock terminal CK is at a low voltage, the second clock terminal XCK is at a high voltage, the first node N1, the second node N2, the fifth node N5, and the sixth node N6 are at high voltages, the third node N3 and the fourth node N4 are at low voltages, and the first output terminal OUT1 outputs a high voltage.

In the second stage t2, the reset signal terminal RST is at a high voltage, the trigger signal terminal STV is at a low voltage, the first clock terminal CK is at a high voltage, the second clock terminal XCK is at a low voltage, the first node N1, the second node N2 and the sixth node N6 are at high voltages, the third node N3, the fourth node N4, and the fifth node N5 are at low voltages, and the first output terminal OUT1 outputs a high voltage.

In the third stage t3, the reset signal terminal RST is at a high voltage, the trigger signal terminal STV is at a low voltage, the first clock terminal CK is at a low voltage, the second clock terminal XCK is at a high voltage, the first node N1, the second node N2, the third node N3, the fifth node N5, and the sixth node N6 are at a low voltage, the fourth node N4 is at a high voltage, and the first output terminal OUT1 outputs a low voltage.

In the fourth stage t4, the reset signal terminal RST is at a high voltage, the trigger signal terminal STV is at a low voltage, the first clock terminal CK is at a high voltage, the second clock terminal XCK is at a low voltage, the first node N1, the second node N2, and the sixth node N6 are at low voltages, the third node N3, the fourth node N4, and the fifth node N5 are at high voltages, and the first output terminal OUT1 outputs a low voltage.

It can be understood that in the third stage t3, the sixth transistor M6 and the seventh transistor M7 are turned on, and the first electrode of the first capacitor C1 is at a high voltage; in the fourth stage t4, the seventh transistor M7 is turned on, and the first electrode of the first capacitor C1 jumps to a low voltage, so that the sixth node N6 jumps to a lower voltage. Since the eighth transistor M8 isolates the sixth node N6 from the first node N1, the voltage of the first node N1 does not jump lower.

The operation of the fifth stage t5 is the same as that of the third stage t3 and will not be described in detail here.

The operation of the sixth stage t6 is the same as that of the fourth stage t4, and will not be described in detail here. It should be noted that in the sixth stage t6, the voltage of the trigger signal terminal STV may be slightly increased by the coupling of the other signals, but this does not affect the normal operation of the shift register.

In the seventh stage t7, the reset signal terminal RST is at a high voltage, the trigger signal terminal STV is at a high voltage, the first clock terminal CK is at a low voltage, the second clock terminal XCK is at a high voltage, the first node N1, the second node N2, the fourth node N4, the fifth node N5, and the sixth node N6 are at high voltages, the third node N3 is at a low voltage, and the first output terminal OUT1 outputs a low voltage. Similarly, in the seventh phase t7, the voltage of the first output terminal OUT1 may be slightly increased by the coupling of the other signals, but this does not affect the normal operation of the shift register.

In the eighth stage t8, the reset signal terminal RST is at a high voltage, the trigger signal terminal STV is at a high voltage, the first clock terminal CK is at a high voltage, the second clock terminal XCK is at a low voltage, the first node N1, the second node N2, and the sixth node N6 are at high voltages, the third node N3, the fourth node N4, and the fifth node N5 are at low voltages, and the first output terminal OUT1 outputs a high voltage.

In the ninth stage t9, the reset signal terminal RST is at a high voltage, the trigger signal terminal STV is at a high voltage, the first clock terminal CK is at a low voltage, the second clock terminal XCK is at a high voltage, the first node N1, the second node N2, the fifth node N5, and the sixth node N6 are at high voltages, the third node N3 and the fourth node N4 are at low voltages, and the first output terminal OUT1 outputs a high voltage.

The eighth stage t8 and the ninth stage t9 are repeated after the ninth stage t9.

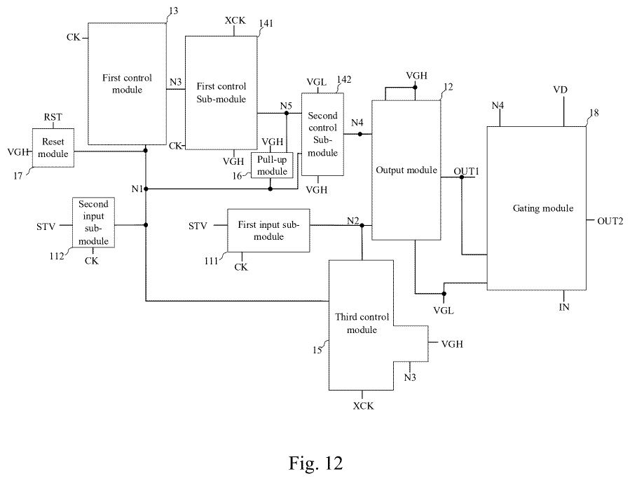

In some embodiments, as shown in FIG. 12, the shift register further includes a gating module 18 which is configured to control the voltage of the second output terminal OUT2 based on the signals of the first output terminal OUT1, the second power supply terminal VGL, the fourth node N4, the third power supply terminal VD, and the start signal terminal IN.

It can be understood that the gating module 18 is electrically connected to the first output terminal OUT1, the second power supply terminal VGL, the fourth node N4, the third power supply terminal VD, the start signal terminal IN, and the second output terminal OUT2.

Illustratively, the signal of the third power supply terminal VD is a fixed high voltage. Illustratively, the voltage at the third power supply terminal VD and the voltage at the first power supply terminal VGH may be equal. In other examples, the voltage at the third power supply terminal VD may not be equal to the voltage at the first power supply terminal VGH.

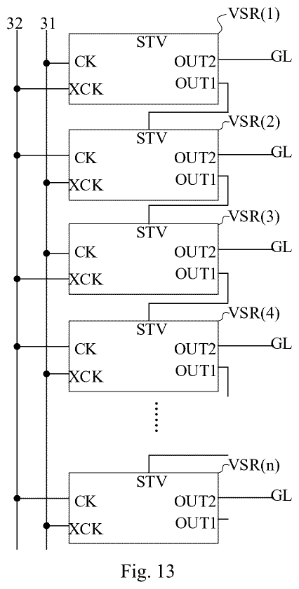

Illustratively, as shown in FIG. 13, in a case where the shift register includes a gating module, a first output terminal OUT1 serves as a cascade signal terminal, and a first output terminal OUT1 of an ith stage of the shift register is electrically connected to a trigger signal terminal STV of an (i+1)^{th} stage of the shift register, i being an integer greater than 0. For example, a first output terminal OUT1 of a first stage shift register VSR (1) is electrically connected to a trigger signal terminal STV of a second stage shift register VSR (2), a first output terminal OUT1 of the second stage shift register VSR (2) is electrically connected to a trigger signal terminal STV of a third stage shift register VSR (3), a first output terminal OUT1 of the third stage shift register VSR (3) is electrically connected to a trigger signal terminal STV of a fourth-stage shift register VSR (4), and so on. And the second output terminal OUT2 serves as a driving signal terminal, the second output terminal OUT2 is electrically connected to the sub-pixel via the scanning line GL, and the signal output by the second output terminal OUT2 is configured to drive the sub-pixel.

As an example, as shown in FIG. 3, the pixel driving circuit includes an amplitude modulation module and a pulse width modulation module, the pulse width modulation module accesses a frequency sweep signal SWEEP, and a signal waveform of a start signal terminal IN includes an oblique angle waveform, so that a second output terminal OUT2 outputs the frequency sweep signal SWEEP to control the pulse width modulation module.

As another example, the signal waveform of the start signal terminal IN includes a square waveform, so that the second output terminal OUT2 outputs a scanning signal to control the amplitude modulation module.

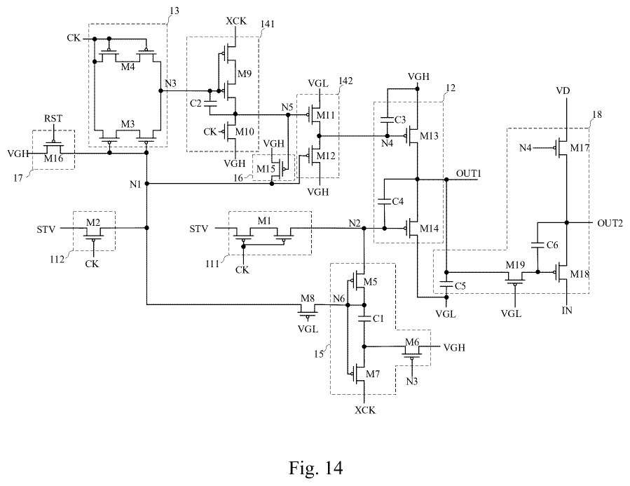

In some embodiments, as shown in FIG. 14, the gating module 18 includes a seventeenth transistor M17, an eighteenth transistor M18, a fifth capacitor C5, and a sixth capacitor C6; a first electrode of the seventeenth transistor M17 is electrically connected to the third power supply terminal VD, a second electrode of the seventeenth transistor M17 is electrically connected to the second output terminal OUT2, and a gate of the seventeenth transistor M17 is electrically connected to the fourth node N4; a first electrode of the eighteenth transistor M18 is electrically connected to the start signal terminal IN, a second electrode of the eighteenth transistor M18 is electrically connected to the second output terminal OUT2, and a gate of the eighteenth transistor M18 is electrically connected to the first output terminal OUT1; the fifth capacitor C5 is electrically connected between the first output terminal OUT1 and the second power supply terminal VGL; the sixth capacitor C6 is electrically connected between the second output terminal OUT2 and the gate of the eighteenth transistor M18.

Illustratively, when the fourth node N4 is at a low voltage, the seventeenth transistor M17 is turned on, and the high voltage at the third power supply terminal VD is transmitted to the second output terminal OUT2. When the first output terminal OUT1 is at a low voltage, the eighteenth transistor M18 is turned on, and the signal at the start signal terminal IN is transmitted to the second output terminal OUT2.

In some embodiments, the channel width-to-length ratio of the seventeenth transistor M17 is greater than that of the transistors in the output module 12, and/or, the channel width-to-length ratio of the eighteenth transistor M18 is greater than that of the transistors in the output module 12. In this way, the driving capability of the signal output by the second output terminal OUT2 can be ensured.

Illustratively, the channel width-to-length ratio of the seventeenth transistor M17 is the same as that of the eighteenth transistor M18, the channel width-to-length ratio of the thirteenth transistor M13 is the same as that of the fourteenth transistor M14, the channel width of the seventeenth transistor M17 is greater than that of the thirteenth transistor M13, and the channel length of the seventeenth transistor M17 is greater than that of the thirteenth transistor M13.

In some embodiments, as shown in FIG. 14, the gating module 18 further includes a nineteenth transistor M19; the gate of the eighteenth transistor M18 is electrically connected to the first output terminal OUT1 via the nineteenth transistor M19, and the gate of the nineteenth transistor M19 is electrically connected to the second power supply terminal VGL.

The nineteenth transistor M19 may be maintained in a conductive state via the first power supply terminal VGL.

In this embodiment, the nineteenth transistor M19 can isolate the first output terminal OUT1 from the gate of the eighteenth transistor M18, so that the voltage of the first output terminal OUT1 can be relatively stably maintained. For example, the voltage of the first output terminal OUT1 does not decrease to be lower than the voltage of the second power supply terminal VGL, so that the bias stress applied to the transistor to which the first output terminal OUT1 is connected can be alleviated.

Illustratively, the channel length of the nineteenth transistor may be greater than the channel length of the transistors in the output module.

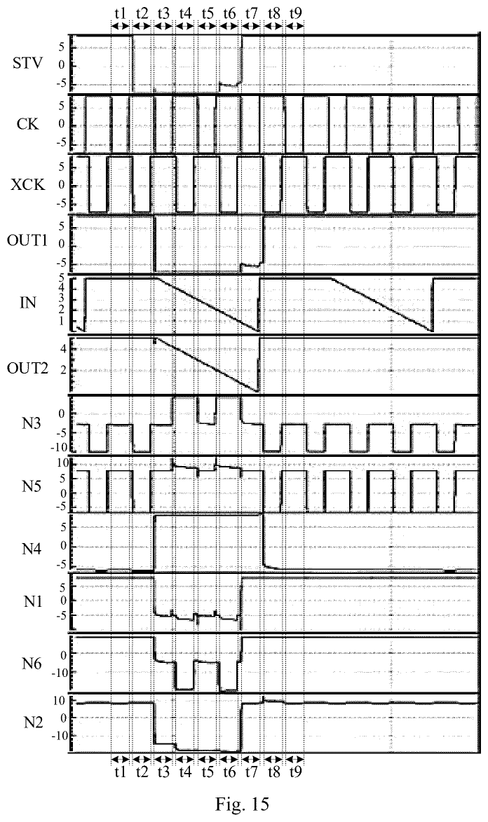

With reference to FIGS. 14 and 15 in combination, the operation of the shift register will be described as an example in which each transistor is a P-type transistor and the signal waveform of the start signal terminal IN includes an oblique angle waveform.

The operation of the shift register still includes a first stage t1 to a ninth stage t9. Compared with Table 1, Table 2 further shows the voltages accessing the gates of the seventeenth transistor M17, the eighteenth transistor M18, and the nineteenth transistor M19 in each stage. Similarly, “O” in Table 2 indicates that the gate of the transistor is connected to a low voltage, and the transistor is conductive; “1” indicates that the gate of the transistor accesses a high voltage and the transistor is turned off. Here, “low voltage” and “high voltage” are relative terms, and “low voltage” refers to a voltage at which the control transistor is turned on, and “high voltage” refers to a voltage at which the control transistor is turned off. The specific value of the “low voltage” to which different transistors are applied may be different, and the specific value of the “high voltage” to which different transistors are applied may be different.

TABLE 2

| | t1 | t2 | t3 | t4 | t5 | t6 | t7 | t8 | t9 |
|---|---|---|---|---|---|---|---|---|---|
| M1 | 0 | 1 | 0 | 1 | 0 | 1 | 0 | 1 | 0 |
| M2 | 0 | 1 | 0 | 1 | 0 | 1 | 0 | 1 | 0 |
| M3 | 1 | 1 | 0 | 0 | 0 | 0 | 1 | 1 | 1 |
| M4 | 0 | 1 | 0 | 1 | 0 | 1 | 0 | 1 | 0 |
| M5 | 1 | 1 | 0 | 0 | 0 | 0 | 1 | 1 | 1 |
| M6 | 0 | 0 | 0 | 1 | 0 | 1 | 0 | 0 | 0 |
| M7 | 1 | 1 | 0 | 0 | 0 | 0 | 1 | 1 | 1 |
| M8 | 0 | 0 | 0 | 0 | 0 | 0 | 0 | 0 | 0 |
| M9 | 0 | 0 | 0 | 1 | 0 | 1 | 0 | 0 | 0 |
| M10 | 0 | 1 | 0 | 1 | 0 | 1 | 0 | 1 | 0 |
| M11 | 1 | 0 | 1 | 1 | 1 | 1 | 1 | 0 | 1 |
| M12 | 1 | 1 | 0 | 0 | 0 | 0 | 1 | 1 | 1 |
| M13 | 0 | 0 | 1 | 1 | 1 | 1 | 1 | 0 | 0 |
| M14 | 1 | 1 | 0 | 0 | 0 | 0 | 1 | 1 | 1 |
| M15 | 1 | 0 | 1 | 1 | 1 | 1 | 1 | 0 | 1 |
| M16 | 0 | 1 | 1 | 1 | 1 | 1 | 1 | 1 | 1 |
| M17 | 0 | 0 | 1 | 1 | 1 | 1 | 1 | 0 | 0 |
| M18 | 1 | 1 | 0 | 0 | 0 | 0 | 0 | 1 | 1 |
| M19 | 0 | 0 | 0 | 0 | 0 | 0 | 0 | 0 | 0 |

In each stage, the first power source terminal VGH maintains a high voltage, the second power source terminal VGL maintains a low voltage, and the third power source terminal VD maintains a high voltage. Illustratively, the voltage value of the third power supply terminal VD is the same as that of the first power supply terminal VGH.

The similarities between FIG. 15 and FIG. 11 will not be described again, and the differences include the following.

In the first stage t1 and the second stage t2, the first output terminal OUT1 outputs a high voltage, the fourth node N4 is at a low voltage, the seventeenth transistor M17 is turned on, the high voltage of the third power supply terminal VD is transmitted to the second output terminal OUT2, and the second output terminal OUT2 outputs a high voltage.

In the third stage t3 to the seventh stage t7, the first output terminal OUT1 outputs a low voltage, the fourth node N4 is at a high voltage, the eighteenth transistor M18 is turned on, the oblique angle waveform signal at the start signal terminal IN is transmitted to the second output terminal OUT2, and the second output terminal OUT2 outputs the oblique angle waveform signal. Illustratively, the voltage of the oblique angle waveform signal is greater than or equal to zero.

In the eighth stage t8 and the ninth stage t9, the first output terminal OUT1 outputs a high voltage, the fourth node N4 is at a low voltage, the seventeenth transistor M17 is turned on, the high voltage of the third power supply terminal VD is transmitted to the second output terminal OUT2, and the second output terminal OUT2 outputs a high voltage.

The eighth stage t8 and the ninth stage t9 are repeated after the ninth stage t9.

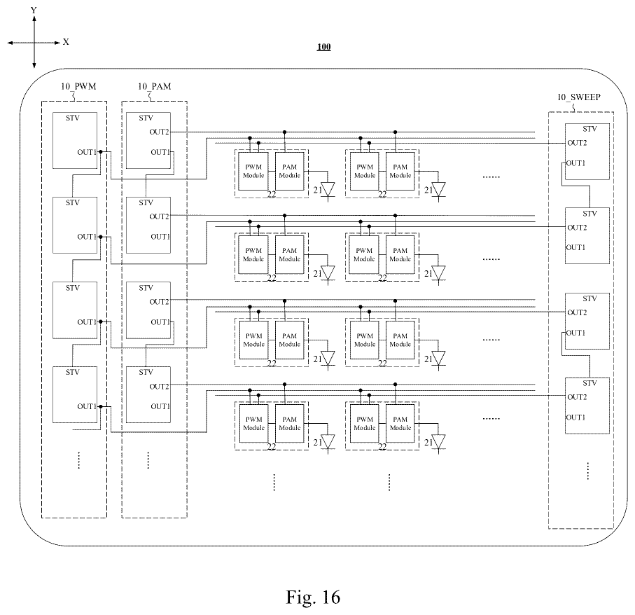

In some embodiments, as shown in FIG. 16, the sub-pixel 20 includes a light-emitting element 21 and a pixel driving circuit 22 for driving the light-emitting element 21. The pixel driving circuit 22 includes a PWM (Pulse Width Modulation) module and a PAM (Pulse Amplitude Modulation) module, and the combination of the PWM module and the PAM module can control the intensity of a driving current and the duration of the driving current to control the light-emitting state of the light-emitting element.

The PWM module is connected to the PAM module. The pixel circuit generates a drive current under the control of the PWM module and the PAM module. The PAM module is configured to control the amplitude of the drive current, and the PWM module is configured to adjust the pulse width of the voltage applied to the first electrode of the light-emitting element.

The PWM module adjusts the pulse width of the voltage applied to the first electrode of the light-emitting element, i.e. the PWM module adjusts the actual emission period during which the driving current is applied to the light-emitting element, while maintaining the driving current applied to the light-emitting element at a constant level to adjust the gradation or brightness displayed by the light-emitting element, instead of adjusting the gradation or brightness displayed by the light-emitting element only by adjusting the magnitude of the driving current applied to the light-emitting element. Therefore, the PAM module can supply the driving current to the light-emitting element such that the light-emitting element is driven at the optimum light-emitting efficiency and adjust the light emission duty ratio (i.e. the emission period of the light-emitting element) of the light-emitting element by the PWM module to adjust the gradation or brightness displayed by the light-emitting element.

The gate driving circuit 10 includes a first gate driving circuit 10_PWM including a shift register as shown in any one of FIG. 5, FIG. 7, FIG. 8, FIG. 9, and FIG. 10; a second gate driving circuit 10_PAM including a shift register as shown in FIG. 12 or FIG. 14; and a third gate driving circuit 10_SWEEP including a shift register as shown in FIG. 12 or FIG. 14. The first gate driving circuit 10_PWM includes a shift register as shown in FIG. 5, FIG. 7, FIG. 8, FIG. 9, and FIG. 10. In other words, the first gate driving circuit 10_PWM does not include a gating module, and the second gate driving circuit 10_PAM and the third gate driving circuit 10 SWEEP each includes a gating module.

The second gate driving circuit 10_PAM is electrically connected to the PAM module, and the first gate driving circuit 10_PWM and the third gate driving circuit 10 SWEEP are electrically connected to the PWM module. A first output terminal OU1 of the first gate driving circuit 10_PWM is configured to output a first light-emission control signal Emit1, a second output terminal OUT of the second gate driving circuit 10_PAM is configured to output a second light-emission control signal Emit2, and a second output terminal OUT of the third gate driving circuit 10_SWEEP is configured to output a frequency sweep signal SWEEP.

For ease of identification, the start signal terminal of the second gate driving circuit 10 PAM is labeled IN PAM, and the start signal terminal of the third gate driving circuit 10 SWEEP is labeled IN SWEEP. The start signal terminal IN_PAM of the second gate driving circuit 10_PAM and the start signal terminal IN_SWEEP of the third gate driving circuit 10_SWEEP have different signal timing.

For example, the start signal terminal IN_PAM of the second gate driving circuit 10_PAM is a square wave signal, and the signal waveform of the start signal terminal IN SWEEP of the third gate driving circuit 10_SWEEP includes an oblique angle waveform.

In a case where the shift register does not include a gating module, the signal output at the first output of the shift register can be adjusted only according to the row time as a minimum amount of change. The gating time of the PAM module in the pixel driving circuit is related to the light-emitting effect of the light-emitting element, and the second gate driving circuit 10_PAM includes a gating module. In this way, by adjusting the signal waveform of the start signal terminal IN PAM of the second gate driving circuit 10_PAM, the adjustment of 1:N to the second output terminal OUT2 of the second gate driving circuit 10_PAM may be achieved, so that the adjustment precision of the second light-emitting control signal Emit2 output by the second gate driving circuit 10_PAM is higher, where 1:N refers to the first row of sub-pixels to the N^{th} row of sub-pixels, and N is an integer greater than 1.

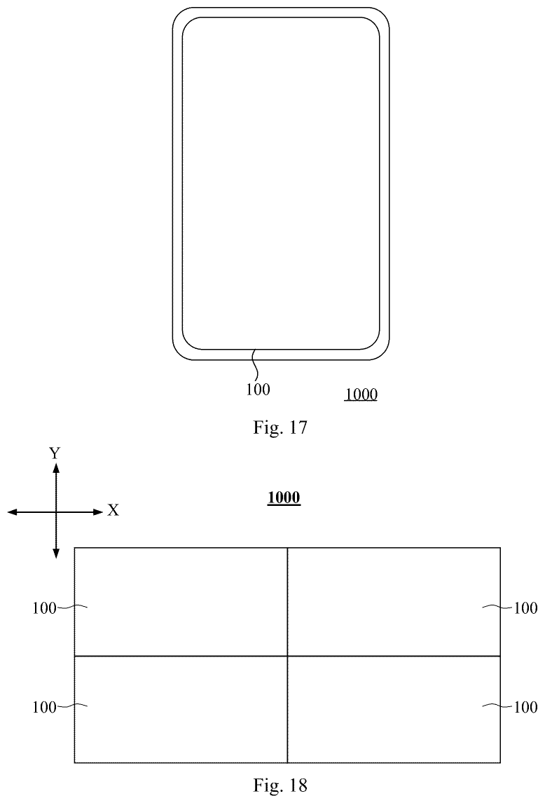

Embodiments of the present application further provide a display apparatus, including a display panel provided by embodiments of the present application. With reference to FIG. 17, which is a schematic structural view of a display apparatus according to an embodiment of the present application. FIG. 17 provides a display apparatus 1000 that includes a display panel 100 provided by any of the above-described embodiments of the present application. In the embodiment of FIG. 17, only a mobile phone is used as an example to describe the display apparatus 1000, and it may be understood that the display apparatus provided by embodiments of the present application may be a wearable product, a computer, a television, a vehicle-mounted display apparatus, or other display apparatus having a display function, which is not specifically limited in the present application. The display apparatus provided by the embodiment of the present application has the beneficial effects of the display panel provided by embodiments of the present application, and reference may be made to the specific description of the display panel in the above embodiments, which will not be repeated herein.

The display apparatus provided by embodiments of the present application may be a tiled display apparatus, such as a rimless tiled display apparatus, including at least two of the above-described display panels 100, so as to be suitable for a large-screen display apparatus having a display function.

At least two display panels 100 may be arranged in the first direction X or at least two display panels 100 may be arranged in the second direction Y, the present application is not limited thereto, and the present application is not particularly limited thereto.

The display apparatus 1000 provided in embodiments of the present application can be a mobile phone as shown in FIG. 17, a tiled display apparatus as shown in FIG. 18, and any electronic product with a display function, including but not limited to the following categories: embodiments of the present application are not particularly limited with respect to televisions, notebook computers, and desktop displays.

As with the embodiments described above in accordance with the present application, these embodiments are not intended to be exhaustive or to limit the application to the precise embodiments described. Obviously, many modifications and variations are possible in light of the above teaching. Embodiments were chosen and described in detail in order to best explain the principles of the application and its practical application, to thereby enable others skilled in the art to well utilize the application and various modifications thereof. The present application is to be limited only by the claims and the full scope and equivalents thereof.

What is claimed is:

1. A gate driving circuit comprising a plurality of shift registers connected in cascade, a shift register of the shift registers comprising:
an input module configured to control a voltage of a first node and a voltage of a second node based on a signal of a trigger signal terminal and a signal of a first clock terminal;
a first control module configured to control a voltage of a third node based on the signal of the first clock terminal and a signal of the first node;
a second control module configured to control a voltage of a fourth node based on the signal of the first node, a signal of the third node, a signal of a first power supply terminal, a signal of a second power supply terminal, the signal of the first clock terminal, and a signal of a second clock terminal;
a third control module configured to control the voltage of the second node based on the signal of the first node, the signal of the third node, the signal of the first power supply terminal, and the signal of the second clock terminal; and
an output module configured to control a voltage of a first output terminal based on a signal of the second node, a signal of the fourth node, the signal of the first power supply terminal, and the signal of the second power supply terminal.

2. The gate driving circuit according to claim 1, wherein the second control module comprises:
a first control sub-module configured to control a voltage of a fifth node based on the signal of the third node, the signal of the first power supply terminal, the signal of the first clock terminal, and the signal of the second clock terminal; and
a second control sub-module configured to control the voltage of the fourth node based on the signal of the first node, a signal of the fifth node, the signal of the first power supply terminal, and the signal of the second power supply terminal.

3. The gate driving circuit according to claim 2, wherein the shift register further comprises a pull-up module configured to control the voltage of the first node based on the signal of the fifth node and the signal of the first power supply terminal.

4. The gate driving circuit according to claim 1, wherein the shift register further comprises a reset module configured to control the voltage of the first node based on the signal of the first power supply terminal and a signal of a reset signal terminal.

5. The gate driving circuit according to claim 1, wherein the input module comprises:
a first input sub-module configured to control the voltage of the second node based on the signal of the trigger signal terminal and the signal of the first clock terminal; and
a second input sub-module configured to control the voltage of the first node based on the signal of the trigger signal terminal and the signal of the first clock terminal.

6. The gate driving circuit according to claim 5, wherein
the first input sub-module comprises a first transistor, a first electrode of the first transistor being electrically connected to the trigger signal terminal, a second electrode of the first transistor being electrically connected to the second node, and a gate of the first transistor being electrically connected to the first clock terminal; and
the second input sub-module comprises a second transistor, a first electrode of the second transistor being electrically connected to the trigger signal terminal, a second electrode of the second transistor being electrically connected to the first node, and a gate of the second transistor being electrically connected to the first clock terminal.

7. The gate driving circuit according to claim 1, wherein the first control module comprises:
a third transistor, a first electrode of the third transistor being electrically connected to the first clock terminal, a second electrode of the third transistor being electrically connected to the third node, and a gate of the third transistor being electrically connected to the first node; and
a fourth transistor, a first electrode and a gate of the fourth transistor being electrically connected to the first clock terminal, and a second electrode of the fourth transistor being electrically connected to the third node.

8. The gate driving circuit according to claim 1, wherein the third control module comprises:
a fifth transistor, a first electrode and a gate of the fifth transistor being electrically connected to a sixth node, and a second electrode of the fifth transistor being electrically connected to the second node;
a sixth transistor, a first electrode of the sixth transistor being electrically connected to the first power supply terminal, and a gate of the sixth transistor being electrically connected to the third node;
a seventh transistor, a first electrode of the seventh transistor being electrically connected to the second clock terminal, a second electrode of the seventh transistor being electrically connected to the first electrode of the first capacitor, and a gate of the seventh transistor being electrically connected to the sixth node; and
a first capacitor, a first electrode of the first capacitor being electrically connected to a second electrode of the sixth transistor, a second electrode of the first capacitor being electrically connected to the sixth node, and the sixth node being electrically connected to the first node.

9. The gate driving circuit according to claim 8, wherein the sixth node is electrically connected to the first node via an eighth transistor, and a gate of the eighth transistor is electrically connected to the second power supply terminal.

10. The gate driving circuit according to claim 2, wherein the first control sub-module comprises:
a ninth transistor, a first electrode of the ninth transistor being electrically connected to the second clock terminal, a second electrode of the ninth transistor being electrically connected to the fifth node, and a gate of the ninth transistor being electrically connected to the third node;
a tenth transistor, a first electrode of the tenth transistor being electrically connected to the first power supply terminal, a second electrode of the tenth transistor being electrically connected to the fifth node, and a gate of the tenth transistor being electrically connected to the first clock terminal; and
a second capacitor, a first electrode of the second capacitor being electrically connected to the third node, and a second electrode of the second capacitor being electrically connected to the fifth node.

11. The gate driving circuit according to claim 2, wherein the second control sub-module comprises:
an eleventh transistor, a first electrode of the eleventh transistor being electrically connected to the second power supply terminal, a second electrode of the eleventh transistor being electrically connected to the fourth node, and a gate of the eleventh transistor being electrically connected to the fifth node; and
a twelfth transistor, a first electrode of the twelfth transistor being electrically connected to the first power supply terminal, a second electrode of the twelfth transistor being electrically connected to the fourth node, and a gate of the twelfth transistor being electrically connected to the first node.

12. The gate driving circuit according to claim 1, wherein the output module comprises:
a thirteenth transistor, a first electrode of the thirteenth transistor being electrically connected to the first power supply terminal, a second electrode of the thirteenth transistor being electrically connected to the first output terminal, and a gate of the thirteenth transistor being electrically connected to the fourth node;
a fourteenth transistor, a first electrode of the fourteenth transistor being electrically connected to the second power supply terminal, a second electrode of the fourteenth transistor being electrically connected to the first output terminal, and a gate of the fourteenth transistor being electrically connected to the second node;
a third capacitor electrically connected between the first power supply terminal and the fourth node; and
a fourth capacitor electrically connected between the second node and the first output terminal.

13. The gate driving circuit according to claim 3, wherein the pull-up module comprises a fifteenth transistor, a first electrode of the fifteenth transistor being electrically connected to the first power supply terminal, a second electrode of the fifteenth transistor being electrically connected to the first node, and a gate of the fifteenth transistor being electrically connected to the fifth node.

14. The gate driving circuit according to claim 4, wherein the reset module comprises a sixteenth transistor, a first electrode of the sixteenth transistor being electrically connected to the first power supply terminal, a second electrode of the sixteenth transistor being electrically connected to the first node, and a gate of the sixteenth transistor being electrically connected to the reset signal terminal.

15. The gate driving circuit according to claim 1, wherein the shift register further comprises a gating module configured to control a voltage of a second output terminal based on a signal of the first output terminal, the signal of the second power supply terminal, the signal of the fourth node, a signal of a third power supply terminal, and a signal of a start signal terminal.

16. The gate driving circuit according to claim 15, wherein the gating module comprises:
a seventeenth transistor, a first electrode of the seventeenth transistor being electrically connected to the third power supply terminal, a second electrode of the seventeenth transistor being electrically connected to the second output terminal, and a gate of the seventeenth transistor being electrically connected to the fourth node;
an eighteenth transistor, a first electrode of the eighteenth transistor being electrically connected to the start signal terminal, a second electrode of the eighteenth transistor being electrically connected to the second output terminal, and a gate of the eighteenth transistor being electrically connected to the first output terminal;
a fifth capacitor electrically connected between the first output terminal and the second power supply terminal; and
a sixth capacitor electrically connected between the second output terminal and the gate of the eighteenth transistor.

17. The gate driving circuit according to claim 16, wherein the gating module further comprises a nineteenth transistor, the gate of the eighteenth transistor being electrically connected to the first output terminal via the nineteenth transistor, and a gate of the nineteenth transistor being electrically connected to the second power supply terminal.

18. The gate driving circuit according to claim 16, wherein a channel width-to-length ratio of the seventeenth transistor is greater than that of a transistor in the output module; and/or
a channel width-to-length ratio of the eighteenth transistor is greater than that of the transistor in the output module.

19. A display panel, comprising a sub-pixel and a gate driving circuit which is electrically connected to the sub-pixel and comprises a plurality of shift registers connected in cascade, a shift register of the shift registers comprising:
an input module configured to control a voltage of a first node and a voltage of a second node based on a signal of a trigger signal terminal and a signal of a first clock terminal;
a first control module configured to control a voltage of a third node based on the signal of the first clock terminal and a signal of the first node;
a second control module configured to control a voltage of a fourth node based on the signal of the first node, a signal of the third node, a signal of a first power supply terminal, a signal of a second power supply terminal, the signal of the first clock terminal, and a signal of a second clock terminal;
a third control module configured to control the voltage of the second node based on the signal of the first node, the signal of the third node, the signal of the first power supply terminal, and the signal of the second clock terminal; and
an output module configured to control a voltage of a first output terminal based on a signal of the second node, a signal of the fourth node, the signal of the first power supply terminal, and the signal of the second power supply terminal.

20. A display apparatus, comprising a display panel which comprises a sub-pixel and a gate driving circuit electrically connected to the sub-pixel,
wherein the gate driving circuit comprises a plurality of shift registers connected in cascade, a shift register of the shift registers comprising:
an input module which is configured to control a voltage of a first node and a voltage of a second node based on a signal of a trigger signal terminal and a signal of a first clock terminal;
a first control module configured to control a voltage of a third node based on the signal of the first clock terminal and a signal of the first node;
a second control module configured to control a voltage of a fourth node based on the signal of the first node, a signal of the third node, a signal of a first power supply terminal, a signal of a second power supply terminal, the signal of the first clock terminal, and a signal of a second clock terminal;
a third control module configured to control the voltage of the second node based on the signal of the first node, the signal of the third node, the signal of the first power supply terminal, and the signal of the second clock terminal; and
an output module configured to control a voltage of a first output terminal based on a signal of the second node, a signal of the fourth node, the signal of the first power supply terminal, and the signal of the second power supply terminal.
